(19) United States
(12) Patent Application Publication
(10) Pub. No.: US 2007/0026647 A1
(43) Pub. Date: Feb. 1, 2007

(54) Method for forming polycrystalline silicon thin film

(75) Inventors: Chi-Ming Chang, Kaohsiung City (TW); Jung-Fang Chang, Yongkang City (TW); Hung-Tse Chen, Zhubei City (TW); Te-Chi Wong, Yizhu Shiang (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 11/245,208

(22) Filed: Oct. 7, 2005

(30) Foreign Application Priority Data
Jul. 29, 2005 (TW) 094125713

(51) Int. Cl. H01L 21/20; H01L 21/36

(52) U.S. Cl. 438/486

(57) ABSTRACT

A method for forming a polycrystalline silicon thin film, comprising steps of: providing a substrate; forming an amorphous silicon thin film on the substrate; and inducing a plurality of eddy currents to heat up the substrate such that the amorphous silicon thin-film is annealed to form the polycrystalline silicon thin film.

### BACKGROUND OF THE INVENTION

1. Field of the Invention

The present invention generally relates to a method for forming a polycrystalline silicon thin film and, more particularly, to a method for forming a polycrystalline silicon thin film using high-frequency annealing so as to form the polycrystalline silicon thin film with improved reliability and lowered cost.

2. Description of the Prior Art

The flexible display has attracted considerable attention in the industry of flat panel displays due to its compactness and portability. It is usually fabricated on a plastic substrate instead of the conventional glass substrate that has been used in liquid crystal displays (LCD's) and organic light emitting diode (OLED).

However, the plastic substrate suffers from its low melting point and is thus not suitable for high-temperature manufacturing of polysilicon-based devices. On the other hand, the thermal expansion coefficient of the plastic substrate is much larger than that of the glass substrate, and therefore problems due to interface stress may damage the devices. Moreover, the plastic substrate often generates statistic charges when being rubbed, which causes reduction of the lifetime and reliability of the devices.

In U.S. Pat. No. 6,642,092, Voutsas et al disclose a solid-phase crystallization (SPC) technique for forming polysilicon-based devices on a metal substrate. In flexible display applications, the metal substrate is advantageous over the plastic substrate for its high melting point and being free of statistic charges. However, the above-mentioned prior art reference is disadvantageous because the process is complicated and the cost is high.

Therefore, there is need in providing a method for forming a polycrystalline silicon thin film to overcome the problems that appear in the prior art so as to improve the reliability and lifetime of the polysilicon-based devices and reduce the manufacturing cost.

### SUMMARY OF THE INVENTION

It is a primary object of the present invention to provide a method for forming a polycrystalline silicon thin film, using a metal or magnetic substrate so as to increase the reliability and lifetime of the polysilicon-based device.

It is a secondary object of the present invention to provide a method for forming a polycrystalline silicon thin film using high-frequency annealing so as to form the polycrystalline silicon thin film with lowered cost.

In order to achieve the foregoing objects, in one embodiment, the present invention provides a method for forming a polycrystalline silicon thin film, comprising steps of: providing a substrate; forming an amorphous silicon thin film on the substrate; and inducing a plurality of eddy currents to heat up the amorphous silicon thin film on the substrate to form the polycrystalline silicon thin film.

In another embodiment, the present invention further provides a method for forming a polycrystalline silicon thin film, comprising steps of: providing a substrate; forming an amorphous silicon thin film on the substrate; forming an insulating layer on the amorphous silicon thin film; and inducing a plurality of eddy currents to heat up the amorphous silicon thin film on the substrate to form the polycrystalline silicon thin film.

In still another embodiment, the present invention further provides a method for forming a polycrystalline silicon thin film for a flexible display, comprising steps of: providing a flexible substrate on a machine; forming an amorphous silicon thin film on the flexible substrate; and inducing a plurality of eddy currents to heat up the amorphous silicon thin film on the flexible substrate to form the polycrystalline silicon thin film.

In still another embodiment, the present invention further provides a method for forming a polycrystalline silicon thin film for a flexible display, comprising steps of: providing a flexible substrate on a machine; forming an amorphous silicon thin film on the flexible substrate; forming an insulating layer on the amorphous silicon thin film; and inducing a plurality of eddy currents to heat up the amorphous silicon thin film on the flexible substrate to form the polycrystalline silicon thin film.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a schematic diagram describing a method for forming a polycrystalline silicon thin film in accordance with the present invention;

FIG. 2 is a cross-sectional view of a structure formed using a method for forming a polycrystalline silicon thin film in accordance with the present invention; and

FIG. 3 is a schematic diagram describing a method for forming a polycrystalline silicon thin film for a flexible display in accordance with the present invention.

### DETAILED DESCRIPTION OF THE PREFERRED EMBODIMENT

The present invention providing a method for forming a polycrystalline silicon thin film can be exemplified by the preferred embodiments as described hereinafter.

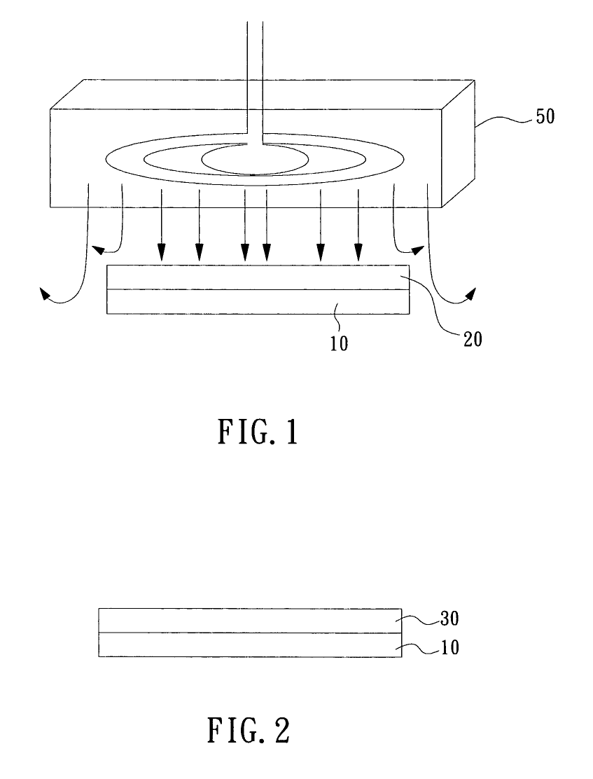

Please refer to FIG. 1, which is a schematic diagram describing a method for forming a polycrystalline silicon thin film in accordance with the present invention. In FIG. 1, there is provided a substrate 10, on which an amorphous silicon thin film 20 is formed. A heating device 50 is used to heat up the amorphous silicon thin film 20 so as to form a polycrystalline silicon thin film 30 as shown in FIG. 2. Preferably, the heating device 50 is a high-frequency annealing device.

The substrate 10 is a metal or magnetic substrate. The substrate 10 can also be implemented using a flexible substrate. Preferably, the metal substrate 10 is a stainless steel foil.

In one preferred embodiment, the high-frequency annealing device 50 comprises a radio frequency (RF) generator so as to perform high-frequency annealing on the amorphous silicon thin film 20 on the metal substrate 10. During the high-frequency annealing process, a plurality of local eddy currents are induced by the variation of the magnetic flux in the substrate 10, which has been described by Faraday's Law. The induced local eddy currents then generate heat in the substrate 10 according to Ohm's Law, and the amorphous silicon thin film 20 is thus heated to reach the crystallization temperature and become a polycrystalline silicon thin film.

The polycrystalline silicon thin film formed is applicable to the flexible display industry. Therefore, an insulating layer such as an oxide layer, a nitride layer or an oxynitride layer can further be formed on the amorphous silicon thin film 20. Once the amorphous silicon thin film 20 is crystallized into a polycrystalline silicon thin film 30, the conventional high-cost and low-throughput laser annealing can be prevented. Moreover, the substrate 10 is favorable because it exhibits good thermal conductivity and it helps to crystallize the amorphous silicon thin film 20 rapidly and uniformly.

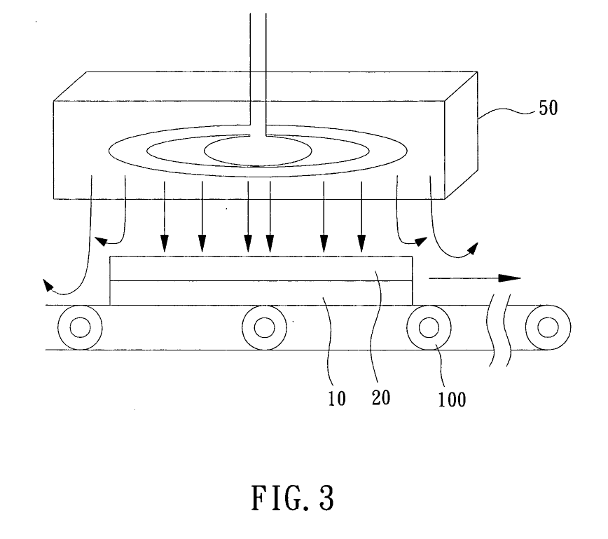

Please further refer to FIG. 3, which is a schematic diagram describing a method for forming a polycrystalline silicon thin film for a flexible display in accordance with the present invention. In FIG. 3, there is provided a flexible substrate 10 on a roll-to-roll machine 100. An amorphous silicon thin film 20 is formed on the flexible substrate 10. A heating device 50 is used to perform annealing on the amorphous silicon thin film 20 so as to form a polycrystalline silicon thin film 30 as shown in FIG. 2. Preferably, the heating device 50 is a high-frequency annealing device.

The flexible substrate 10 is a metal or magnetic substrate. Preferably, the metal substrate 10 is a stainless steel foil.

In one preferred embodiment, the high-frequency annealing device 50 comprises a radio frequency (RF) generator so as to perform high-frequency annealing on the amorphous silicon thin film 20 on the flexible substrate 10.

In the traditional iron and steel industry, high-frequency (or RF) annealing is a well-developed technique. Adopting the roll-to-toll process as disclosed in the present invention, the industry can easily manufacture a polycrystalline silicon thin film on a flexible metal substrate with lowered cost and improved reliability compared to the conventional plastic substrate.

Accordingly, it is apparent that the present invention discloses a method for forming a polycrystalline silicon thin film using a frequency-tunable device to anneal amorphous silicon on a metal substrate so as to form the polycrystalline silicon thin film with improved reliability and lowered cost. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for forming a polycrystalline silicon thin film, comprising steps of:
providing a substrate;
forming an amorphous silicon thin film on said substrate; and
inducing a plurality of eddy currents to heat up said amorphous silicon thin film on said substrate to form said polycrystalline silicon thin film.

2. The method as recited in claim 1, wherein said substrate is a flexible substrate.

3. The method as recited in claim 1, wherein said substrate is a metal substrate.

4. The method as recited in claim 3, wherein said metal substrate is a stainless steel foil.

5. The method as recited in claim 1, wherein said substrate is a magnetic substrate.

6. The method as recited in claim 1, wherein said eddy currents are induced using a high-frequency annealing device.

7. The method as recited in claim 6, wherein said high-frequency annealing device comprises a radio-frequency (RF) generator.

8. A method for forming a polycrystalline silicon thin film, comprising steps of:
providing a substrate;
forming an amorphous silicon thin film on said substrate;
forming an insulating layer on said amorphous silicon thin film; and
inducing a plurality of eddy currents to heat up said amorphous silicon thin film on said substrate to form said polycrystalline silicon thin film.

9. The method as recited in claim 8, wherein said substrate is a flexible substrate.

10. The method as recited in claim 8, wherein said substrate is a metal substrate.

11. The method as recited in claim 10, wherein said metal substrate is a stainless steel foil.

12. The method as recited in claim 8, wherein said substrate is a magnetic substrate.

13. The method as recited in claim 8, wherein said insulating layer is an oxide layer.

14. The method as recited in claim 8, wherein said insulating layer is a nitride layer.

15. The method as recited in claim 8, wherein said insulating layer is an oxynitride layer.

16. The method as recited in claim 8, wherein said eddy currents are induced using a high-frequency annealing device.

17. The method as recited in claim 16, wherein said high-frequency annealing device comprises a radio-frequency (RF) generator.

18. A method for forming a polycrystalline silicon thin film for a flexible display, comprising steps of:
providing a flexible substrate on a machine;
forming an amorphous silicon thin film on said flexible substrate; and
inducing a plurality of eddy currents to heat up said amorphous silicon thin film on said flexible substrate to form said polycrystalline silicon thin film.

19. The method as recited in claim 18, wherein said flexible substrate is a metal substrate.

20. The method as recited in claim 19, wherein said metal substrate is a stainless steel foil.

21. The method as recited in claim 18, wherein said flexible substrate is a magnetic substrate.

22. The method as recited in claim 18, wherein said eddy currents are induced using a high-frequency annealing device.

23. The method as recited in claim 22, wherein said high-frequency annealing device comprises a radio-frequency (RF) generator.

24. The method as recited in claim 18, wherein said machine is a roll-to-roll machine.

25. A method for forming a polycrystalline silicon thin film for a flexible display, comprising steps of:
providing a flexible substrate on a machine;
forming an amorphous silicon thin film on said flexible substrate;
forming an insulating layer on said amorphous silicon thin film; and
inducing a plurality of eddy currents to heat up said amorphous silicon thin film on said flexible substrate to form said polycrystalline silicon thin film.

26. The method as recited in claim 25, wherein said flexible substrate is a metal substrate.

27. The method as recited in claim 26, wherein said metal substrate is a stainless steel foil.

28. The method as recited in claim 25, wherein said flexible substrate is a magnetic substrate.

29. The method as recited in claim 25, wherein said insulating layer is an oxide layer.

30. The method as recited in claim 25, wherein said insulating layer is a nitride layer.

31. The method as recited in claim 25, wherein said insulating layer is an oxynitride layer.

32. The method as recited in claim 25, wherein said eddy currents are induced using a high-frequency annealing device.

33. The method as recited in claim 32, wherein said high-frequency annealing device comprises a radio-frequency (RF) generator.

34. The method as recited in claim 25, wherein said machine is a roll-to-roll machine.
